(19) United States
(12) Patent Application Publication
(10) Pub. No.: US 2026/0198014 A1
(43) Pub. Date: Jul. 9, 2026

(54) MAGNETORESISTIVE MEMORY DEVICE AND METHOD OF MANUFACTURING THE SAME

(71) Applicant: SK hynix Inc., Gyeonggi-do (KR)

(72) Inventor: Cha Deok DONG, Gyeonggi-do (KR)

(21) Appl. No.: 19/214,037

(22) Filed: May 21, 2025

(30) Foreign Application Priority Data
Jan. 6, 2025 (KR) 10-2025-0001643

(51) Int. Cl. H10B 61/00; H10N 50/01; H10N 50/10

(52) U.S. Cl. CPC H10B 61/10; H10N 50/01; H10N 50/10

(57) ABSTRACT

A method of manufacturing a magnetoresistive memory device may include forming a magnetic tunnel junction layer over a substrate; forming a hard mask pattern on the magnetic tunnel junction layer; etching the magnetic tunnel junction layer using the hard mask pattern to form a residual hard mask pattern; adjusting a thickness of the residual hard mask pattern remaining after etching the magnetic tunnel junction layer to form a passivation pattern; and forming at least one signal line using an additional hard mask pattern and the passivation pattern to protect the magnetic tunnel junction layer.

### CROSS-REFERENCES TO RELATED APPLICATION

The present application claims priority under 35 U.S.C. § 119(a) to Korean application number 10-2025-0001643, filed on Jan. 6, 2025, which is incorporated herein by reference in its entirety.

### BACKGROUND

### 1. Technical Field

Embodiments of the present disclosure relate generally to an electronic device and a method of manufacturing the same, and more particularly to a magnetoresistive memory device including a magnetic tunnel junction pattern and a method of manufacturing the magnetoresistive memory device.

### 2. Related Art

A resistive change memory device may include a plurality of word lines, a plurality of bit lines and a plurality of resistive variable memory cells, operatively connected to the word lines and the bit lines.

The plurality of word lines and bit lines may be arranged perpendicularly to each other. Each resistance variable memory cell may be positioned at the intersections of the word lines and bit lines. Each of these memory cells may include a memory layer.

Depending on the type of memory layer, the resistance variable memory cells can be categorized as MRAM (Magnetic Random Access Memory), ReRAM (Resistive Random Access Memory), PcRAM (Phase-change Random Access Memory), or FeRAM (Ferroelectric Random Access Memory) cells.

Among the resistive variable memory cells, MRAM cells stand out due to their fast operating speed and excellent rewriting characteristics. Consequently, a resistance variable memory device with MRAM cells can be effectively utilized as code storage or working memory in an information system.

### SUMMARY

Embodiments of the present disclosure provide an electronic device that can be capable of preventing loss of memory layers, thereby ensuring electrical reliability.

Embodiments of the present disclosure also provide a method of manufacturing the above-mentioned electronic devices.

According to some embodiments of the present disclosure, there is provided a method of manufacturing a magnetoresistive memory device. The method may include forming a magnetic tunnel junction layer over a substrate; forming a hard mask pattern on the magnetic tunnel junction layer; etching the magnetic tunnel junction layer using the hard mask pattern to form a residual hard mask pattern; adjusting a thickness of the residual hard mask pattern remaining after etching the magnetic tunnel junction layer to form a passivation pattern; and forming at least one signal line using an additional hard mask pattern and the passivation pattern to protect the magnetic tunnel junction layer.

According to some embodiments of the present disclosure, there is provided a method of manufacturing a magnetoresistive memory device. The method may include forming a first signal line extending in a first direction over a substrate; forming a plurality of switching structures on the first signal line; forming an insulating interlayer between the plurality of switching structures; forming a magnetic tunnel junction layer on the plurality of switching structures and the insulating interlayer; forming a plurality of hard mask patterns to have a first thickness on the magnetic tunnel junction layer; patterning the magnetic tunnel junction layer using the hard mask patterns to form a plurality of magnetic tunnel junction patterns; forming a sidewall protective layer on a sidewall of the magnetic tunnel junction patterns and a sidewall of residual hard mask patterns located on the magnetic tunnel junction patterns, the residual hard mask patterns having a second thickness thinner than the first thickness; and selectively growing the residual hard mask patterns exposed by the sidewall protective layer to form a plurality of passivation patterns having a target thickness greater than the second thickness.

In some embodiments of the present disclosure, when the hard mask patterns include a material including a transition metal, forming the passivation patterns may include reacting the residual hard mask patterns with silicon to form silicide patterns.

In some embodiments of the present disclosure, when the hard mask patterns include a material including silicon, forming the passivation patterns may include epitaxially growing the residual hard mask patterns.

According to some embodiments of the present disclosure, there may be provided a magnetoresistive memory device. The magnetoresistive memory device may include a first signal line extending in a first direction; a switching structure disposed on the first signal line in a pillar shape; a resistive structure disposed on the switching structure in a pillar shape; and a second signal line contacting an upper surface of the resistive structure and extending in a second direction perpendicular to the first direction. The resistive structure may include a magnetic tunnel junction pattern located on the switching structure; a conductive passivation pattern disposed to contact at least a portion of the magnetic tunnel junction pattern and at least a portion of the second signal line, respectively; and a sidewall protective layer disposed to surround an entire sidewall of the magnetic tunnel junction pattern and a lower sidewall of the conductive passivation pattern and expose an upper sidewall of the conductive passivation pattern.

According to some embodiments of the present disclosure, the hard mask pattern configured to define the magnetic tunnel junction pattern may be formed with a thickness that is perfectly patterned to a lower region of the magnetic tunnel junction layer so that the hard mask pattern may be separated, to form the magnetic tunnel junction pattern. Thereafter, the thickness of the residual hard mask pattern may be selectively grown by an initial thickness to form a passivation pattern. Accordingly, in the process of forming the second signal line on the passivation pattern, even if a hard mask pattern for the second signal line may be misaligned, a loss of the magnetic tunnel junction pattern may be prevented by the passivation pattern. Since the loss of the magnetic tunnel junction pattern corresponding to the storage layer, i.e., the memory layer, may be prevented, electrical reliability of the electronic device may be secured.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a schematic perspective view illustrating a resistive memory device in accordance with an embodiment of the present disclosure;

FIG. 2 is a schematic cross-sectional view illustrating a resistive memory cell in accordance with an embodiment of the present disclosure; and

FIGS. 3 to 9 are cross-sectional views illustrating a method of manufacturing a magnetoresistive memory device in accordance with embodiments of the present disclosure.

### DETAILED DESCRIPTION

The advantages and features of the present invention, and methods of achieving them, will become apparent upon reference to the embodiments described in detail with reference to the accompanying drawings. However, the invention is not limited to the embodiments disclosed herein, but can be embodied in many different forms. These embodiments are provided merely to make the present disclosure complete and to provide a description of the embodiments to one of ordinary skill in the art. The dimensions and relative sizes of the layers and regions in the drawings may be exaggerated for clarity of description. Throughout the specification, like reference numerals refer to like components.

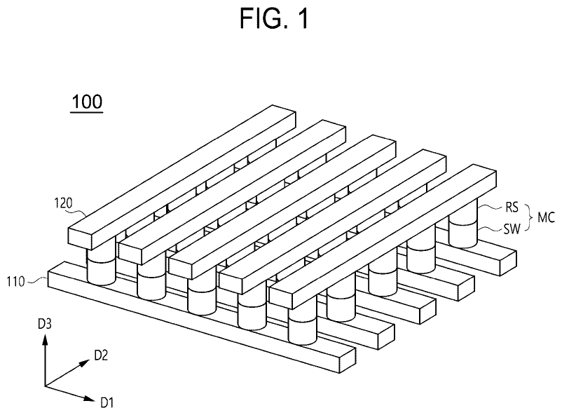

FIG. 1 is a schematic perspective view illustrating a resistive memory device in accordance with an embodiment of the present disclosure.

Referring to FIG. 1, a magnetoresistive memory device 100 may include a plurality of first signal lines 110, a plurality of second signal lines 120 and a plurality of resistive memory cells MCs.

The plurality of first signal lines 110 may be arranged in parallel along a first direction D1. For example, the plurality of first signal lines 110 may be a plurality of word lines or a plurality of bit lines. The first signal lines 110 may include a conductive material. For example, the conductive material may include at least one of a metal compound, and a metal nitride. The metal compound may include platinum (Pt), tungsten (W), aluminum (Al), copper (Cu), tantalum (Ta). The metal nitride may include titanium nitride (TiN), tantalum nitride (TaN), or combinations thereof. The first signal lines 110 may include a single-layer structure or a multi-layer structure.

The plurality of second signal lines 120 may be disposed over the plurality of first signal lines 110. The plurality of second signal lines 120 may extend in parallel along a second direction D2 intersecting the first direction D1. The plurality of second signal lines 120 may be, for example, a plurality of bit lines or a plurality of word lines. The second signal line 120 may include a variety of conductive materials, such as metals such as platinum (Pt), tungsten (W), aluminum (Al), copper (Cu), tantalum (Ta), metal nitrides such as titanium nitride (TiN), tantalum nitride (TaN), or combinations thereof, and may have a single-layer structure or a multi-layer structure.

The plurality of resistive memory cells MCs may be positioned at intersections between the plurality of the first signal lines 110 and the plurality of the second signal lines 120, respectively. At least one of the resistive memory cells MC may include a switching structure SW and a resistive structure RS. The switching structure SW may control the resistive structure RS.

The switching structure SW may be provided for each resistive memory cell MC to reduce disturbance issues generated in a cross point memory device. For example, the switching structure SW may control the operation of the resistance memory cell MC to prevent unselected resistance memory cells MC from an abnormal turn-on operation due to leakage current between the first and second signal lines 110 and 120.

The resistive structure RS may selectively store data under the control of the switching structure SW.

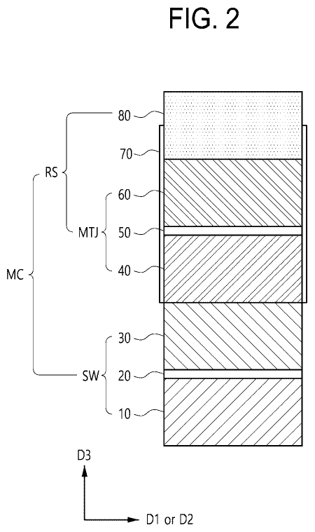

FIG. 2 is a schematic cross-sectional view illustrating a resistive memory cell in accordance with an embodiment of the present disclosure.

Referring to FIG. 1 and FIG. 2, the switching structure SW of the resistive memory cell MC may be interposed between the first signal line 110 and the resistive structure RS. The switching structure SW may include a lower electrode 10, a selector 20 and a middle electrode 30. The selector 20 may be disposed between the lower and middle electrodes 10 and 30.

For example, the lower electrode 10 may make contact with the first signal line 110. The lower electrode 10 may receive a voltage or current applied to the first signal line 110.

The selector 20 may be interposed between the lower electrode 10 and the middle electrode 30 and may be selectively changed to a conductive state based on a voltage difference between the lower electrode 10 and the middle electrode 30. For example, if the voltage difference between the lower electrode 10 and the middle electrode 30 is no less than a threshold voltage, the selector 20 may be turned on to the conductive state. If the voltage difference between the lower electrode 10 and the middle electrode 30 is no more than the threshold voltage, the selector 20 may be turned off to an insulated state.

For example, the selector 20 may include an insulation material including conductive impurities. In some embodiments, the selector 20 may include a silicon oxide layer (SiO₂) including Arsenic (As) ions.

The middle electrode 30 may be positioned over the selector 20. For example, the middle electrode 30 may be in a floating state. When the selector 20 is turned on to be conductive, a voltage from the first signal line 110 may be transferred to the middle electrode 30 via the lower electrode 10 and selector 20. The middle electrode 30 may include a conductive material.

For example, the resistive structure RS may be interposed between the switching structure SW and the second signal line 120. The resistive structure RS may selectively store data based on a voltage difference between a voltage of the middle electrode 30 and a voltage of the second signal line 120. For example, the resistive structure RS may include a magnetic tunnel junction pattern MTJ, a sidewall protective layer 70 and a passivation pattern 80.

The magnetic tunnel junction pattern MTJ may include a fixed layer 40, a tunnel barrier layer 50 and a free layer 60. The fixed layer 40 may be disposed over the middle electrode 30.

For example, the fixed layer 40 may include a material for providing a fixed magnetization direction.

The tunnel barrier layer 50 may be positioned between the fixed layer 40 and the free layer 60. The tunnel barrier layer 50 may include an insulation material capable of electrically insulating the fixed layer 40 and the free layer 60. Further, the tunnel barrier layer 50 may have a relatively thin thickness, such as a thickness of about 5 Å to about 30 Å, capable of tunneling charges between the fixed layer 40 and the free layer 60 under a selected condition.

The free layer 60 may include a material whose magnetization direction changes depending on the voltage or current applied to the second signal line 120. For example, the magnetization direction of the free layer 60 may be changed by a spin transfer torque generated by the voltage (or current) applied to the second signal line 120. Depending on a difference between the magnetization direction of the free layer 60 and the magnetization direction of the fixed layer 40, a resistance of the magnetic tunnel junction pattern MTJ may be changed. The free layer 60 may be disposed below the passivation pattern 80.

The passivation pattern 80 may be formed on the magnetic tunnel junction pattern MTJ. For example, the passivation pattern 80 may be formed on the free layer 60 of the magnetic tunnel junction pattern MTJ. When the second signal line 120 is etched, the passivation pattern 80 may prevent loss of the magnetic tunnel junction pattern MTJ. For example, the passivation pattern 80 may include an etch selectivity with respect to the magnetic tunnel junction pattern MTJ. Further, the passivation pattern 80 may include a conductive material. Alternately, the passivation pattern 80 may be selectively expanded in a volume by a thermal treatment.

The sidewall protective layer 70 may be formed to surround a sidewall of the magnetic tunnel junction pattern MTJ and a lower portion of the sidewall of the passivation pattern 80. An upper portion of the sidewall of the passivation pattern 80 may be exposed from the sidewall protective layer 70.

Although not shown in the drawings, an upper electrode may be interposed between the resistive structure RS and the second signal line 120. Alternatively, the passivation pattern 80 may be utilized as the upper electrode.

As such, the resistive memory cell MC may have a pillar shape. Further, while some embodiments illustrate the resistive structure RS being positioned over the switching structure SW, the switching structure SW may also be disposed over the resistive structure RS.

Although in FIG. 2, a width of the switching structure SW and a width of the resistive structure RS are shown to be uniform, at least one of the switching structure SW and the resistive structure RS may have a width gradually increased toward the bottom, due to an aspect ratio of the switching structure SW and an aspect ratio of the resistive structure RS. For example, the aspect ratio of the switching structure SW may be a ratio of the height to the line width of the switching structure SW, and the aspect ratio of the resistive structure RS may be a ratio of the height to the line width of the resistive structure.

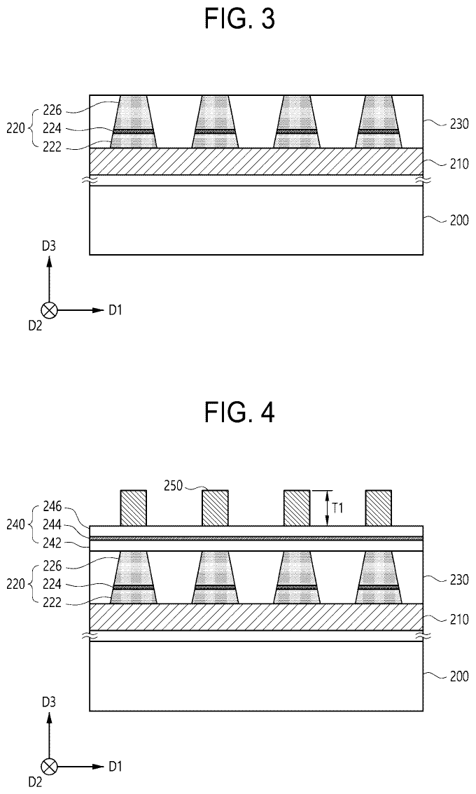

FIGS. 3 to 9 are cross-sectional views illustrating a method of manufacturing a magnetoresistive memory device in accordance with embodiments of the present disclosure.

Referring to FIG. 3, a first conductive layer (not shown) may be formed over a substrate 200. The first conductive layer may be patterned using a mask pattern (not shown) for defining first signal lines, to form a plurality of first signal lines 210. For example, the plurality of first signal lines 210 may be a plurality of word lines or a plurality of bit lines. The plurality of first signal lines 210 may extend in parallel and at regular intervals along a first direction D1. A lower insulation layer (not shown) may be formed between the plurality of first signal lines 210 to electrically insulate the adjacent first signal lines 210 from each other.

A switching layer may be formed over the plurality of first signal lines 210 and the lower insulation layer. In some embodiments, the switching layer may include a second conductive layer, a selector layer and a third conductive layer. In some embodiments, the second conductive layer and the third conductive layer may include a metal layer such as titanium and tantalum, or a metal nitride layer such as titanium nitride and tantalum nitride. The selector layer may include a material capable of controlling a flow of a current, depending on a magnitude of a voltage or a current. For example, the selector layer may be an insulation layer including conductive impurities.

The switching layer may be patterned (or etched) to form a switching structure 220 having a pillar shape over the first signal line 210. The switching structures 220 may be spaced apart from each other by a uniform gap. For example, the switching structures 220 may each include a lower electrode 222 including the second conductive layer, a selector 224 including the selector layer, and a middle electrode 226 including the third conductive layer.

As an integration density of the memory device may be increased, a width of the switching structure 220 may be significantly smaller relative to a thickness of the switching structure 220. Accordingly, the switching structure 220 may have a high aspect ratio. As the switching structure 220 has the high aspect ratio, the switching structure 220 may have a width that increases from the top to the bottom. In order to avoid bridging at a lower tail portion of the switching structure 220, the switching layer may be over-etched. While the over-etching of the switching layer may result in some removal of an upper surface of the first signal line 210, the over-etching may be performed such that electrical properties of the first signal line 210 may not be affected.

For insulating between the switching structures 220, an insulating interlayer 230 may be formed between the switching structures 220, on the first signal line 210 and the lower insulation layer. Subsequently, the insulating interlayer 230 may be planarized to expose the upper surface of the switching structures 220.

Referring to FIG. 4, a magnetic tunnel junction layer 240 may be formed on the switching structures 220 and the insulating interlayer 230. For example, the magnetic tunnel junction layer 240 may include a fixed layer 242, a tunnel barrier layer 244, and a free layer 246 sequentially stacked.

The fixed layer 242 may provide a fixed magnetization direction. The fixed layer 242 may include at least one of iron manganese (FeMn), iridium manganese (IrMn), platinum manganese (PtMn), manganese(II) oxide (MnO), manganese(II) sulfide (MnS), manganese(II) telluride (MnTe), manganese(II) fluoride (MnF2), iron(II) fluoride (FeF2), iron(II) chloride (FeCl2), iron(II) oxide (FeO), cobalt(II) chloride (CoCl2), cobalt(II) oxide (CoO), nickel(II) chloride (NiCl2), nickel(II) oxide (NiO), and chromium (Cr).

The tunnel barrier layer 244 may be formed of a material capable of insulating the fixed layer 242 and the free layer 246, but also capable of causing a tunneling between the fixed layer 242 and the free layer 246. For example, the tunnel barrier layer 244 may include magnesium oxide (MgOx) or aluminum oxide (AlOx).

The free layer 246 may be formed of a material whose magnetization direction is changed by an external stimulus. According to the change in the magnetization direction of the free layer 246, a resistance of the magnetic tunnel junction layer 240 may be changed. According to the change in resistance of the magnetic tunnel junction layer 240, the magnetic tunnel junction layer 240 may exhibit different data states. Consequently, it may be the magnetization direction of the free layer 246 that determines the data state of the magnetic tunnel junction layer 240. Thus, the free layer 246 may be a substantial storage layer. The free layer 246 may have a single-layer structure or a multi-layer structure, for example, including a ferromagnetic material. For example, the free layer 246 may include an alloy based on Fe, Ni, or Co, such as Fe—Pt alloy, Fe—Pd alloy, Co—Pd alloy, Co—Pt alloy, Fe—Ni—Pt alloy, Co—Fe—Pt alloy, Co—Ni—Pt alloy, Co—Fe—B alloy, or the like, or may include a laminated structure of metals, such as a laminated structure of Co/Pt, Co/Pd, or the like.

A hard mask pattern 250 may be formed over the magnetic tunnel junction layer 240. For example, a position and a shape of the hard mask pattern 250 may correspond to a position and a shape of the switching structure 220. Further, the hard mask pattern 250 may be formed of a material having a conductive property, having an etch selectivity with the magnetic tunnel junction layer 240.

It may be desirable that the hard mask pattern 250 may be formed with an appropriate thickness for perfect patterning of the magnetic tunnel junction layer 240 and protection of the magnetic tunnel junction layer 240.

For example, if the thickness of the hard mask pattern 250 may be too thin, the hard mask pattern 250 may be lost before the magnetic tunnel junction layer 240 may be fully patterned. As a result, the magnetic tunnel junction layer 240 may not be defined as the pillar shape, or an upper portion of the magnetic tunnel junction layer 240 may be removed.

Furthermore, after patterning the magnetic tunnel junction layer 240, if a thickness of the residual hard mask pattern may be too thin, or if no residual hard mask pattern may exist, a misalignment of the mask (not shown) for defining the second signal line 120 (see FIG. 1) may cause the magnetic tunnel junction pattern located at a bottom to be lost upon patterning of the second signal line.

On the other hand, if the thickness of the hard mask pattern 250 may be too thick, it may be difficult to completely etch a lower portion of the magnetic tunnel junction layer 240.

Accordingly, the hard mask pattern 250 of some embodiments may be formed with the sufficient thickness to pattern the magnetic tunnel junction layer 240, but the thickness of the residual hard mask pattern 250 may be adjusted to compensate for the thickness of the hard mask pattern 250 lost upon patterning of the magnetic tunnel junction layer 240

In some embodiments, the hard mask pattern 250 may be formed to have a first thickness T1, taking into account the etch selectivity with the magnetic tunnel junction layer 240 and the thickness of the magnetic tunnel junction layer 240. The first thickness T1 may be enough to allow the hard mask pattern 250 to remain on the magnetic tunnel junction layer 240, even after patterning the magnetic tunnel junction layer 240.

For example, the first thickness T1 may have a ratio of about 0.75 to about 1.5 of the thickness of the magnetic tunnel junction layer 240, meaning that the first thickness T1 may be approximately 0.75 to 1.5 times the thickness of the magnetic tunnel junction layer 240. In some embodiments, the magnetic tunnel junction layer 240 may be formed to have a thickness of about 15 nm to about 25 nm, and the hard mask pattern 250 may be formed to have a thickness of about 11.25 nm to about 37.5 nm.

For example, the hard mask pattern 250 may be formed of a conductive material that may selectively be volumetrically expanded by certain treatments. As will be described in more detail below, the specific treatment may be changed depending on the material of the hard mask pattern 250.

For example, the hard mask pattern 250 may include a layer of a transition metal including at least one of tungsten (W), titanium (Ti), tungsten nitride (WNx), titanium nitride (TiNx), cobalt (Co), and nickel (Ni).

Alternatively, the hard mask pattern 250 may include a silicon-containing material layer including conductive impurities. The silicon-containing material layer may include an amorphous silicon layer, a polysilicon layer, or a silicon germanium layer.

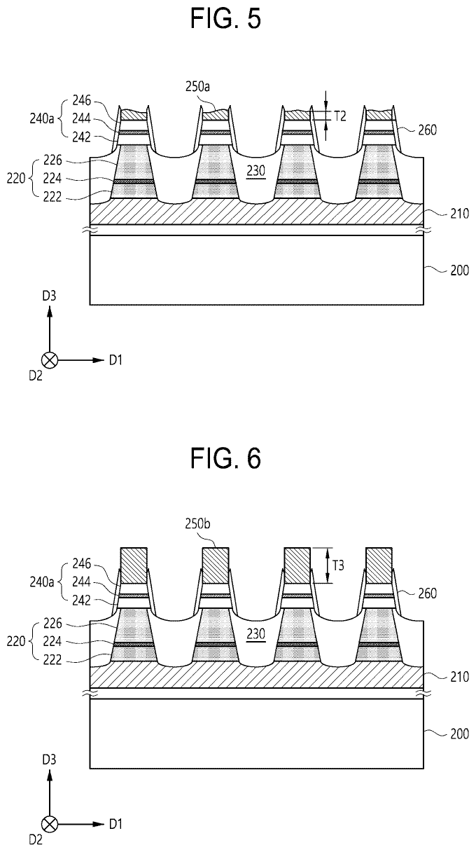

Referring to FIG. 5, using the hard mask pattern 250, the magnetic tunnel junction layer 240 may be etched to form a magnetic tunnel junction pattern 240a. The magnetic tunnel junction pattern 240a may be electrically insulated from other neighboring magnetic tunnel junction patterns 240a.

In some embodiments, the magnetic tunnel junction layer 240 may be patterned by a plurality of ion beam etching (IBE) processes. The plurality of IBE processes may pattern the magnetic tunnel junction layer 240 in a physical-chemical manner by ion beams in a plurality of oblique directions not perpendicular to a surface of the substrate 200. The diagonal direction may include a direction that is ±15° to ±45° with respect to the surface of the substrate 200.

During or after performing the plurality of IBE processes, a sidewall protective layer 260 may be formed over sidewalls of a residual hard mask pattern 250a and sidewalls of the magnetic tunnel junction pattern 240a (or the sidewalls of the middle structure of the magnetic tunnel junction pattern 240a). For example, the sidewall protective layer 260 may be formed by anisotropic etching an insulation layer. For example, the sidewall protective layer 260 may include at least one of SiO₂, SiN₄, SiOCN, and SiON. An upper surface of the residual hard mask pattern 250a may be exposed by the sidewall protective layer 260.

In some embodiments, if n numbers of IBE processes, wherein n is a natural number equal to or greater than 3, are performed to form the magnetic tunnel junction pattern 240a, the sidewall protective layer 260 may be formed after an (n−a)th, where a is a natural number equal to or less than n−2, IBE process.

After performing the plurality of IBE processes, the residual hard mask pattern 250a may have a predetermined thickness removed by the IBE processes, such that the residual hard mask pattern 250a may have a second thickness T2 thinner than the first thickness T1. Further, the residual hard mask pattern 250a may be different from the shape of the hard mask pattern 250 before the IBE etch process.

Since the magnetic tunnel junction pattern 240a may have a high aspect ratio, the IBE processes may proceed beyond a set number of the IBE processes, to electrically isolate adjacent magnetic tunnel junction patterns 240a,

Then, referring to FIG. 6, a thickness, or a volume, of the exposed residual hard mask pattern 250a may be selectively adjusted to the sidewall protective layer 260 as a mask. For example, the residual hard mask pattern 250a having the second thickness T2 may be selectively grown in thickness by a specific treatment to form a passivation pattern 250b having a third thickness T3 greater than the second thickness T2. For example, the third thickness T3 may be equal to or slightly greater than the first thickness T1.

The specific treatment may vary depending on properties of the hard mask patterns 250 and 250a.

In some embodiments, when the hard mask pattern 250 may include a transition metal layer, the specific treatment may include a silicide process. For example, a silicon gas may be provided to the substrate (not shown) to which the residual hard mask pattern 250a is exposed and then thermally treated, thereby forming the silicide pattern by a reaction between the silicon gas and the transition metal material layer. The silicide pattern may have a thickness thicker than a thickness of the transition metal layer.

For example, if the hard mask patterns 250 and 250a include the silicon layer including the conductive impurities, the specific treatment may include an epitaxial growth process using the residual hard mask pattern 250a as a seed layer, thereby an epitaxial pattern. For example, the epitaxial growth process may include a thermal treatment with a silicon gas. A thickness of the epitaxial pattern may be controlled by the amount of the silicon gas and a process time.

The silicide pattern and the epitaxial pattern are not generated on insulating materials. Thus, one of the silicide pattern and the epitaxial pattern is selectively formed on the residual hard mask pattern 250a, to have a target thickness, such as, the third thickness T3. The target thickness may be selected based on a selected thickness to prevent etching of the magnetic tunnel junction pattern 240a in subsequent formation processes of the resistive memory device.

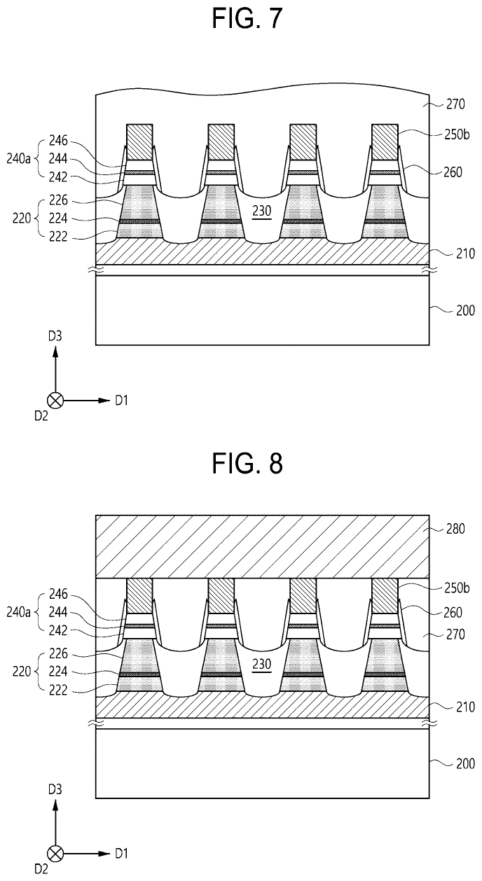

Next, referring to FIG. 7, a capping layer 270 may be formed with a set thickness to fill a gap between the passivation pattern 250b and the magnetic tunnel junction pattern 240a surrounded by the sidewall protective layer 260. The capping layer 270 may include an insulation layer. In some embodiments, the capping layer 270 may include an insulation layer having an etch selectivity with the passivation pattern 250b and the sidewall protective layer 260.

In some embodiments, where the sidewall protective layer 260 may include a silicon oxide layer (SiO2), the capping layer 270 may include a silicon nitride layer (SiN). However, the capping layer 270 is not limited to the above materials, and various insulating layers may be utilized.

The capping layer 270 may be planarized to expose the upper surface of the passivation pattern 250b. For example, the planarization process may include a chemical mechanical polishing (CMP) process or an etch back process. A reference numeral 270a may indicate the planarized capping layer.

Referring to FIG. 8, a fourth conductive layer 280 may be formed on the passivation pattern 250b and capping layer 270a. For example, the fourth conductive layer 280 may include a metal such as tungsten (W) or aluminum (Al) as a conductive layer for forming a second signal line configured to carry a signal for regulating the resistance of the magnetic tunnel junction pattern 240a.

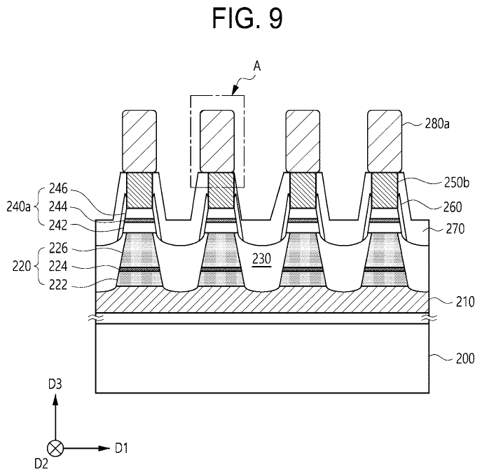

Next, referring to FIG. 9, a mask pattern (not shown) for the second signal lines may be formed on the fourth conductive layer 280. The fourth conductive layer 280 may be etched using the mask pattern, thereby forming a plurality of second signal lines 280a. The mask pattern may include a photoresist material or a hard masking material having an etch selectivity with the fourth conductive layer 280. After forming the second signal line 280a, the mask pattern may be removed in a known manner. For example, the second signal line 280a may be a bit line.

Ideally, the plurality of second signal lines 280a may extend parallel along a second direction D2 perpendicular to the first direction D1, in contact with the upper surface of the passivation pattern 250b.

However, as the integration density of resistance variable memory devices increases, due to various factors, the mask pattern may be formed in a form that is misaligned with the passivation pattern 250b. Accordingly, the mask pattern may overlap with a portion of the passivation pattern 250b. When the fourth conductive layer 280 may be etched using such a misaligned mask pattern, the fourth conductive layer 280 exposed by the misaligned mask pattern and the passivation pattern 250b at a bottom region of the fourth conductive layer 280 may be etched.

For example, if the fourth conductive layer 280 may be formed directly on the residual hard mask pattern 250a without forming the passivation pattern 250b, the misalignment mask pattern may cause the residual hard mask pattern 250a, as well as the magnetic tunnel junction pattern 240a under the residual hard mask pattern 250a, to be removed during the etching process of the fourth conductive layer 280.

However, the thickness of the residual hard mask pattern 250a may be increased to form the passivation pattern 250b having the third thickness T3, even if the misalignment of the mask pattern may be generated, the passivation pattern 250b may remain on the magnetic tunnel junction pattern 240a while the fourth conductive layer 280 may be etched. Accordingly, the magnetic tunnel junction pattern 240a under the passivation pattern 250 may be protected by the passivation pattern 250b.

According to the embodiments of the present disclosure, the hard mask pattern is formed with a selected thickness to ensure complete separation of the magnetic tunnel junction layer. Then, the remaining hard mask pattern after patterning the magnetic tunnel junction layer may be selectively grown by the initial thickness to form a passivation pattern. Accordingly, even if the mask pattern for the second signal line may be misaligned, the loss of the magnetic tunnel junction pattern may be prevented by the passivation pattern.

The loss of the magnetic tunnel junction pattern corresponding to the storage layer, or memory layer, may be prevented, ensuring the electrical reliability of the magnetoresistive memory device.

While the present invention has been described in detail with reference to specific embodiments, the invention is not limited to the above embodiments, but is capable of many modifications by those having ordinary skill in the art within the scope of the technical concepts of the present disclosure. Furthermore, the embodiments may be combined to form additional embodiments.

What is claimed is:

1. A method of manufacturing a magnetoresistive memory device, the method comprising:
forming a magnetic tunnel junction layer over a substrate;
forming a hard mask pattern on the magnetic tunnel junction layer;
etching the magnetic tunnel junction layer using the hard mask pattern to form a residual hard mask pattern;
adjusting a thickness of the residual hard mask pattern remaining after etching the magnetic tunnel junction layer to form a passivation pattern; and
forming at least one signal line using an additional hard mask pattern and the passivation pattern to protect the magnetic tunnel junction layer.

2. The method of claim 1, wherein adjusting the thickness of the residual hard mask pattern comprises performing a thermal treatment to increase the thickness of the residual hard mask pattern by a set thickness.

3. The method of claim 1, further comprising forming, during or after etching the magnetic tunnel junction layer, a sidewall protective layer on a sidewall of the residual magnetic tunnel junction layer and a sidewall of the residual hard mask pattern,
wherein adjusting the thickness of the residual hard mask pattern comprises selectively expanding a volume of the residual hard mask pattern exposed by the sidewall protective layer.

4. The method of claim 3, wherein selectively expanding the volume of the residual hard mask pattern comprises performing a silicide treatment on the hard mask pattern containing a transition metal.

5. The method of claim 3, wherein selectively expanding the volume of the residual hard mask pattern comprises performing an epitaxial growth on the hard mask pattern containing a silicon material doped with conductive impurities.

6. A method of manufacturing a magnetoresistive memory device, the method comprising:
forming a first signal line extending in a first direction over a substrate;
forming a plurality of switching structures on the first signal line;
forming an insulating interlayer between the plurality of switching structures;
forming a magnetic tunnel junction layer on the plurality of switching structures and the insulating interlayer;
forming a plurality of hard mask patterns to have a first thickness on the magnetic tunnel junction layer;
patterning the magnetic tunnel junction layer using the hard mask patterns to form a plurality of magnetic tunnel junction patterns;
forming a sidewall protective layer on a sidewall of the magnetic tunnel junction patterns and a sidewall of residual hard mask patterns located on the magnetic tunnel junction patterns, the residual hard mask patterns having a second thickness thinner than the first thickness; and
selectively growing the residual hard mask patterns exposed by the sidewall protective layer to form a plurality of passivation patterns having a target thickness greater than the second thickness.

7. The method of claim 6, wherein selectively growing the residual hard mask patterns comprises reacting the residual hard mask patterns, containing a transition metal, with a silicon material to form the plurality of passivation patterns being silicide patterns.

8. The method of claim 6, wherein the selectively growing the residual hard mask patterns comprises epitaxially growing the residual hard mask patterns containing silicon material doped with conductive impurities.

9. The method of claim 6, wherein forming the plurality of hard mask patterns comprises:
forming a conductive hard mask layer on the magnetic tunnel junction layer; and
patterning the conductive hard mask layer to remain respectively on the plurality of switching structures.

10. The method of claim 6, wherein patterning the magnetic tunnel junction layer comprises performing, using the hard mask pattern, ion beam etching (IBE) to apply an ion beam to the magnetic tunnel junction layer in an oblique direction n times, where ‘n’ is a natural number equal to or greater than 3.

11. The method of claim 10, wherein the sidewall protective layer is formed between an (n−a)th application of the ion beam and an (n)th application of the ion beam, where ‘a’ is a natural number equal to or less than n−2.

12. The method of claim 6, wherein the sidewall protective layer comprises at least one of SiO₂, SiN₄, SiOCN and SiON.

13. The method of claim 6, wherein the target thickness is equal to or greater than the first thickness.

14. The method of claim 6, further comprising:
forming a capping layer between the plurality of passivation patterns and between the magnetic tunnel junction patterns;
forming a conductive layer on the plurality of passivation patterns and the capping layer; and
patterning the conductive layer to extend along a second direction perpendicular to the first direction and contact the plurality of passivation patterns, to form a plurality of second signal lines.

15. The method of claim 6, wherein forming the plurality of switching structures comprises:
forming a first conductive layer on the first signal line;
forming a selector layer on the first conductive layer;
forming a second conductive layer on the selector layer; and
patterning the second conductive layer, the selector layer and the first conductive layer into a pillar shape to form a bottom electrode, a selector and a middle electrode.

16. The method of claim 6, wherein at least one of the first thickness and the target thickness is 0.75 to 1.5 times a thickness of the magnetic tunnel junction layer.

17. The method of claim 6, wherein the target thickness of the plurality of passivation patterns is determined in contemplation of a process to be applied after the plurality of passivation patterns are formed.

18. A magnetoresistive memory device comprising:
a first signal line extending in a first direction;
a switching structure disposed on the first signal line in a pillar shape;
a resistive structure disposed on the switching structure in a pillar shape; and
a second signal line contacting an upper surface of the resistive structure and extending in a second direction perpendicular to the first direction,
wherein the resistive structure comprises:
a magnetic tunnel junction pattern located on the switching structure;
a conductive passivation pattern disposed to contact at least a portion of the magnetic tunnel junction pattern and at least a portion of the second signal line, respectively; and
a sidewall protective layer disposed to surround an entire sidewall of the magnetic tunnel junction pattern and at least a lower portion of a sidewall of the conductive passivation pattern.

19. The magnetoresistive memory device of claim 18, wherein the conductive passivation pattern is one selected from a silicide layer and a silicon-containing layer having conductivity.

20. The magnetoresistive memory device of claim 18, wherein a thickness of the conductive passivation pattern is 0.75 to 1.5 times a thickness of the magnetic tunnel junction pattern.

21. The magnetoresistive memory device of claim 18, wherein the switching structure comprises:
a lower electrode connected to the first signal line;
a selector disposed on the lower electrode; and
a middle electrode disposed on the selector,
wherein the selector is configured to selectively transmit a current based on a difference between a voltage of the lower electrode and a voltage of the middle electrode.
